(19) United States
(12) Patent Application Publication
(10) Pub. No.: US 2026/0308752 A1
(43) Pub. Date: Oct. 8, 2026

(54) SUBSTRATE PROCESSING METHOD AND SUBSTRATE PROCESSING SYSTEM

(71) Applicant: Tokyo Electron Limited, Tokyo (JP)

(72) Inventors: Fumiaki TANAKA, Tokyo (JP); Masami OIKAWA, Oshu-shi (JP); Kazuya KITAMURA, Oshu-shi (JP); Tomohito YAMAJI, Nirasaki-shi (JP); Hideki KUNUGI, Nirasaki-shi (JP); Hiroyuki TOMITA, Tokyo (JP); Hiroki MAEHARA, Tokyo (JP); Akiyoshi KONDO, Nirasaki-shi (JP)

(73) Assignee: Tokyo Electron Limited, Tokyo (JP)

(21) Appl. No.: 19/682,723

(22) Filed: May 20, 2026

Related U.S. Application Data
(63) Continuation of application No. PCT/JP2024/040233, filed on Nov. 13, 2024.

(30) Foreign Application Priority Data
Nov. 27, 2023 (JP) 2023-199652
Aug. 8, 2024 (JP) 2024-132021

(51) Int. Cl. C23C 16/24; C23C 16/56

(52) U.S. Cl. CPC C23C 16/24; C23C 16/56

(57) ABSTRACT

A substrate processing method including a) forming a silicon-containing layer on each of a first surface and a second surface, the second surface is a back surface of the first surface, of a glass substrate; and b) removing the silicon-containing layer formed on the first surface.

### CROSS-REFERENCE TO RELATED APPLICATIONS

This application is a bypass continuation application of International Application No. PCT/JP 2024/040233 having an international filing date of Nov. 13, 2024 and designating the United States, the International Application being based upon and claiming the benefit of priority from Japanese Patent Applications No. 2023-199652, filed on Nov. 27, 2023, and No. 2024-132021 filed on Aug. 8, 2024, the entire contents of which are incorporated herein by reference.

### BACKGROUND

### Field

Various aspects and embodiments of the present disclosure relate to a substrate processing method and a substrate processing system.

### Background Art

For example, PTL 1 below discloses that, “when a plurality of cut thin plate glass substrates are combined and used as a light guide plate, typically, the cut thin plate glass substrates are stacked and used as the light guide plate. A light guide is applied, for example, to a display device such as a head-mounted display”.

### CITATION LIST

### Patent Documents

PTL 1: JP2022-36174A

### SUMMARY

The present disclosure provides a substrate processing method and a substrate processing system capable of performing processing such as film formation or etching on a glass substrate.

An aspect of the present disclosure is a substrate processing method including a) forming a silicon-containing layer on each of a first surface and a second surface, the second surface is a back surface of the first surface, of a glass substrate; and b) removing the silicon-containing layer formed on the first surface.

### BRIEF DESCRIPTION OF DRAWINGS

The scope of the present disclosure is best understood from the following detailed description of exemplary embodiments when read in conjunction with the accompanying drawings.

FIG. 1 is a system configuration diagram illustrating an example of a substrate processing system according to an embodiment of the present disclosure.

FIG. 2 is a schematic cross-sectional view illustrating an example of a configuration of a film forming apparatus.

FIG. 3 is a diagram illustrating an example of a structure of a boat.

FIG. 4 is an enlarged cross-sectional view illustrating an example of the vicinity of a claw of the boat.

FIG. 5 is a schematic cross-sectional view illustrating an example of an etching apparatus.

FIG. 6 is a plan view illustrating an example of a processing apparatus group.

FIG. 7 is a diagram illustrating an example of a sensing method.

FIG. 8 is a flowchart illustrating an example of a substrate processing method according to a first embodiment.

FIG. 9A is a diagram illustrating an example of a process of processing a glass substrate.

FIG. 9B is a diagram illustrating an example of the process of the processing the glass substrate.

FIG. 9C is a diagram illustrating an example of the process of the processing the glass substrate.

FIG. 10 is a diagram illustrating an example of transmittance for each combination of a film thickness and a wavelength of light when a protective film is polysilicon.

FIG. 11 is a diagram illustrating an example of transmittance for each combination of the film thickness and the wavelength of light when the protective film is amorphous silicon.

FIG. 12 is a flowchart illustrating an example of a substrate processing method according to a second embodiment.

FIG. 13A is a diagram illustrating an example of a process of processing a glass substrate.

FIG. 13B is a diagram illustrating an example of the process of the processing the glass substrate.

FIG. 13C is a diagram illustrating an example of the process of the processing the glass substrate.

FIG. 13D is a diagram illustrating an example of the process of the processing the glass substrate.

FIG. 13E is a diagram illustrating an example of the process of the processing the glass substrate.

FIG. 13F is a diagram illustrating an example of the process of the processing the glass substrate.

### DETAILED DESCRIPTION

Hereinafter, embodiments of a substrate processing method and a substrate processing system disclosed herein will be described in detail with reference to the drawings. The substrate processing method and the substrate processing system disclosed herein are not limited by the following embodiments.

In recent years, microfabrication techniques utilizing a glass substrate is employed to manufacture a high-performance optical element, such as augmented reality (AR) glass. In microfabrication, processing such as etching and film formation are performed on the glass substrate (herein “film” means the same as “layer”).

In a commercially available glass substrate, a metal element used in a manufacturing process may be attached to a surface. Therefore, when processing such as etching or film formation is performed by a processing apparatus using a commercially available glass substrate as it is, a member in the processing apparatus that comes into contact with the glass substrate may be contaminated with a metal element. When a member in the processing apparatus is contaminated with a metal element, the metal element may mix in the process of etching or a film formation with respect to the glass substrate, resulting in a defect of the optical element.

The present disclosure has an aspect capable of reducing metal contamination in a processing apparatus caused by a glass substrate.

### First Embodiment

### Substrate Processing System 10

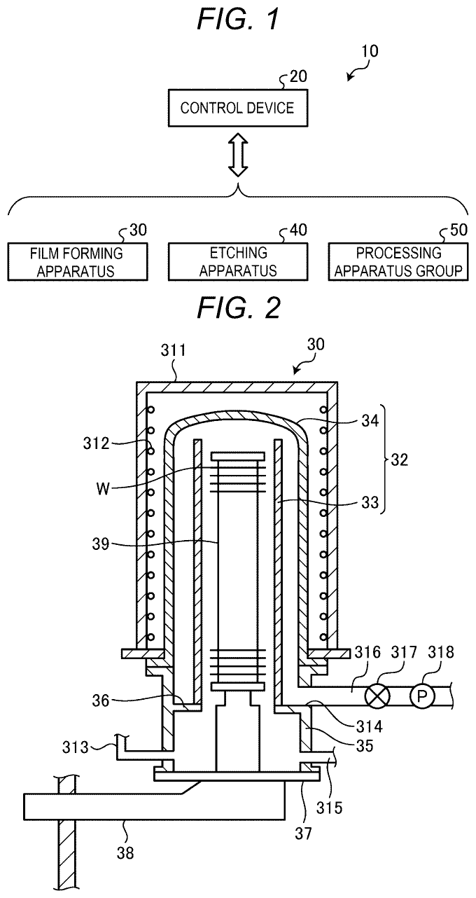

FIG. 1 is a system configuration diagram illustrating an example of a substrate processing system 10 according to an embodiment of the present disclosure. The substrate processing system 10 in the present embodiment includes a control device 20, a film forming apparatus 30, an etching apparatus 40, and a processing apparatus group 50 (herein “film forming apparatus” means the same as “layer forming apparatus”).

The film forming apparatus 30 forms protective films on both surfaces and side surfaces of a glass substrate W, thereby covering both surfaces and side surfaces of the glass substrate W with the protective films. In the present embodiment, the protective film is a silicon-containing film such as polysilicon or amorphous silicon.

The etching apparatus 40 removes the protective film covering a surface (hereinafter, referred to as a first surface) on which processing such as film formation or etching is performed, on the glass substrate W covered with the protective film. The etching apparatus 40 is an example of a removing apparatus.

The processing apparatus group 50 includes a processing apparatus that performs processing such as film formation or etching on the glass substrate W. The processing apparatus performs processing such as film formation or etching on the first surface of the glass substrate W from which the protective film is removed.

The control device 20 includes a memory, a processor, and an input and output interface (herein “control device” means the same as “controller circuitry”). The memory stores data of e.g. a recipe, a program, and/or the like. The memory is, for example, a random access memory (RAM), a read only memory (ROM), a hard disk drive (HDD), or a solid state drive (SSD). The processor is a central processing unit (CPU), a digital signal processor (DSP), or the like. The processor executes a program read from the memory to control each part of the film forming apparatus 30, the etching apparatus 40, and the processing apparatus group 50 via the input and output interface based on data such as a recipe stored in the memory. The control device/controller circuitry 20 can be programmable circuitry (e.g., embedded processor) or fixed circuitry (e.g., ASIC or PAL). In an exemplary embodiment, the controller/controller circuitry 101 can include one or more programmable processors/controllers.

### Configuration of Film Forming Apparatus 30

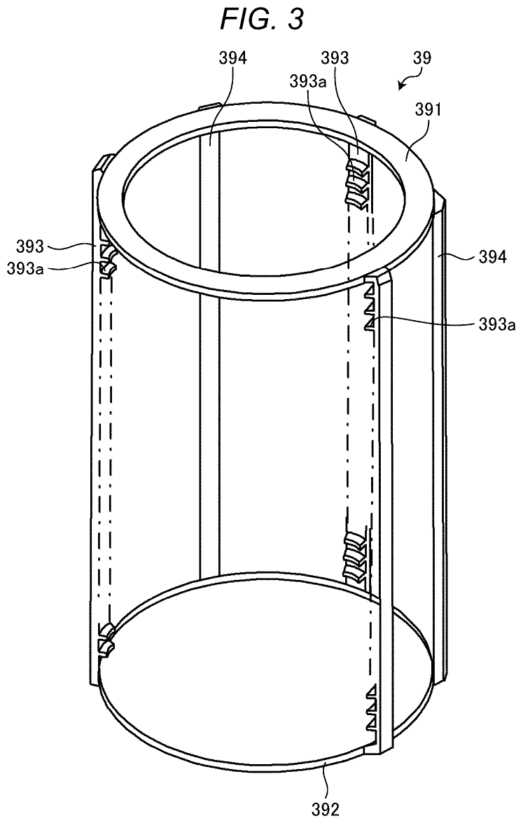

FIG. 2 is a schematic cross-sectional view illustrating an example of a configuration of the film forming apparatus 30. FIG. 2 illustrates a batch-type vertical thermal treatment apparatus as an example of the film forming apparatus 30. The film forming apparatus 30 may be a single-wafer film forming apparatus as long as it is an apparatus capable of forming silicon-containing films on both surfaces and side surfaces of a glass substrate.

The film forming apparatus 30 includes a substantially cylindrical reaction tube 32 whose longitudinal direction extends in a vertical direction. The reaction tube 32 has a double-tube structure that includes an inner tube 33 and an outer tube 34 having a ceiling and formed to cover the inner tube 33 and have a predetermined interval from the inner tube 33. The inner tube 33 and the outer tube 34 are formed of, for example, a material having excellent heat resistance and corrosion resistance, such as quartz.

A manifold 35 made of stainless steel (SUS) or the like and formed in a tubular shape is disposed below the outer tube 34. The manifold 35 is airtightly connected to a lower end of the outer tube 34. The inner tube 33 protrudes from an inner wall of the manifold 35 and is supported by a support ring 36 integrally formed with the manifold 35.

A lid 37 is disposed below the manifold 35. The lid 37 is implemented to be vertically moved by a boat elevator 38. When the lid 37 is raised by the boat elevator 38, a lower side (furnace port portion) of the manifold 35 is closed. When the lid 37 is lowered by the boat elevator 38, the lower side (furnace port portion) of the manifold 35 is opened.

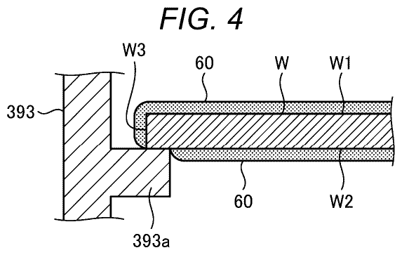

A boat 39 made of, for example, quartz is placed on the lid 37. The boat 39 is implemented to accommodate a plurality of glass substrates W at predetermined intervals along an extending direction of the reaction tube 32. FIG. 3 is a diagram illustrating an example of a structure of the boat 39.

For example, as illustrated in FIG. 3, the boat 39 includes a top plate 391 and a bottom plate 392. A plurality of (three in the example of FIG. 3) support posts 393 are provided between the top plate 391 and the bottom plate 392. Auxiliary posts 394 are provided between the support posts 393. The support posts 393 are provided with claws 393a for supporting the glass substrates W at predetermined intervals. The claws 393a are formed to protrude toward a central direction of the boat 39 and have surfaces substantially parallel to the top plate 391 and the bottom plate 392.

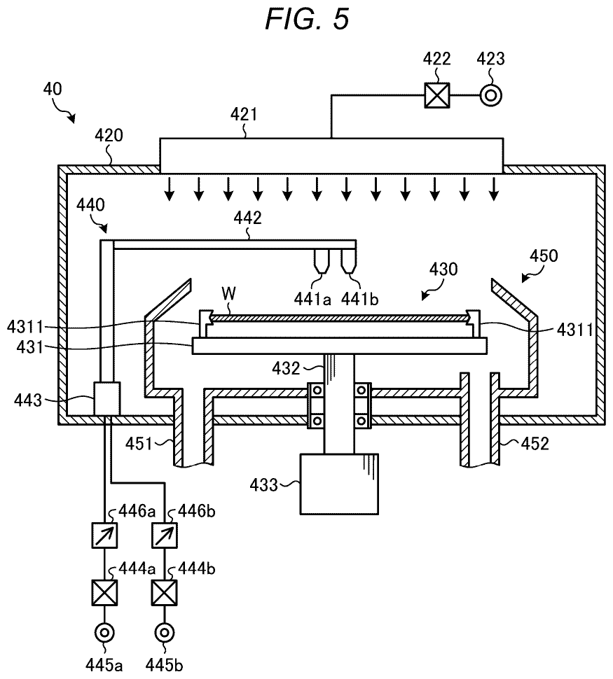

FIG. 4 is an enlarged cross-sectional view illustrating an example of the vicinity of the claw 393a of the boat 39. The claw 393a supports an edge portion of the glass substrate W on an upper surface of the claw 393a. Accordingly, a protective film 60 can be formed on a first surface W1 of the glass substrate W, a second surface W2 of a back surface of the first surface W1, and a side surface W3 of the glass substrate W. The first surface W1 of the glass substrate W is a surface on which an optical element is formed.

Referring back to FIG. 2, the description will be continued. A heat insulator 311 is provided around the reaction tube 32 to surround the reaction tube 32. A heater 312 such as a resistance heating element is provided on an inner wall surface of the heat insulator 311. The inside of the reaction tube 32 is heated to a predetermined temperature by the heater 312, and the glass substrate W is heated to the predetermined temperature.

A pipe 313 for introducing a plurality of processing gases is connected to a side surface of the manifold 35. Specifically, the pipe 313 is connected to the side surface of the manifold 35 below the support ring 36 (below the inner tube 33). The pipe 313 supplies a processing gas into a space inside the reaction tube 32. In the example of FIG. 2, one pipe 313 is illustrated. However, a plurality of pipes 313 may be connected to the inner tube 33 according to the type of the processing gas supplied to the space inside the inner tube 33. In the present embodiment, in order to form the protective film 60 that is a silicon-containing film on the surface of the glass substrate W, for example, a silane gas is used as the processing gas.

The pipe 313 is connected to a processing gas source through a mass flow controller or the like. Accordingly, a predetermined amount of processing gas is supplied from the processing gas source to the space in the reaction tube 32 through the pipe 313.

An exhaust port 314 for exhausting gas from the space inside the reaction tube 32 is provided on the side surface of the manifold 35. The exhaust port 314 is provided above the support ring 36, and communicates with a space formed between the inner tube 33 and the outer tube 34 in the reaction tube 32. An exhaust tube 316 is airtightly connected to the exhaust port 314. The exhaust tube 316 is provided with a valve 317 and a vacuum pump 318. The valve 317 adjusts an opening degree of the exhaust tube 316 to control a pressure in the reaction tube 32 to a predetermined pressure. The vacuum pump 318 exhausts the gas in the reaction tube 32 through the exhaust tube 316.

A pipe 315 for supplying a purge gas is inserted below the exhaust port 314 on the side surface of the manifold 35. A purge gas source is connected to the pipe 315, and a predetermined amount of purge gas (for example, nitrogen gas) is supplied into the reaction tube 32 from the purge gas source through the pipe 315.

### Configuration of Etching Apparatus 40

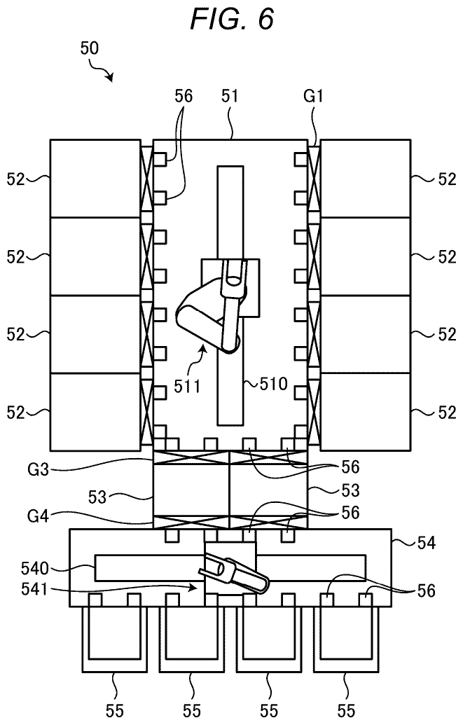

FIG. 5 is a schematic cross-sectional view illustrating an example of the etching apparatus 40. The etching apparatus 40 includes a chamber 420, a substrate holder 430, a liquid supply 440, and a retrieve cup 450.

The chamber 420 accommodates the substrate holder 430, the liquid supply 440, and the retrieve cup 450. A fan filter unit (FFU) 421 is provided in a ceiling portion of the chamber 420. The FFU 421 forms a downflow in the chamber 420.

The FFU 421 is connected to a gas source 423 through a valve 422. The FFU 421 discharges a gas such as dry air supplied from the gas source 423 into the chamber 420.

The substrate holder 430 includes a rotation holder 431, a support post 432, and a driving unit 433. The rotation holder 431 is provided substantially in the center of the chamber 420. A holding member 4311 that holds the glass substrate W from a side surface is provided on an upper surface of the rotation holder 431. The holding member 4311 holds the glass substrate W such that the first surface W1 faces upward. The holding member 4311 horizontally holds the glass substrate W in a state in which the glass substrate W is slightly separated from an upper surface of the rotation holder 431.

The support post 432 is a member extending in the vertical direction, and a base end is rotatably supported by the driving unit 433, and the rotation holder 431 is horizontally supported at a distal end. The driving unit 433 rotates the support post 432 around a vertical axis.

The substrate holder 430 rotates the support post 432 using the driving unit 433 to rotate the rotation holder 431 supported by the support post 432. Accordingly, the glass substrate W held by the rotation holder 431 is rotated.

The rotation holder 431 is not limited to the type that holds the glass substrate W from the side surface, and may be a type that holds the glass substrate W by adsorption from below, such as a vacuum chuck.

The liquid supply 440 supplies various processing liquids to the glass substrate W held by the substrate holder 430. The liquid supply 440 includes a plurality of (two in the example of FIG. 5) nozzles 441a and 441b, an arm 442 that horizontally supports the nozzles 441a and 441b, and a pivoting elevation mechanism 443 that pivots and elevates the arm 442. The nozzles 441a and 441b may be supported by separate arms.

An etching liquid source 445a is connected to the nozzle 441a through a valve 444a and a flow rate adjuster 446a. A rinse liquid source 445b is connected to the nozzle 441b through a valve 444b and a flow rate adjuster 446b.

An etching liquid supplied from the etching liquid source 445a is discharged from the nozzle 441a. The etching liquid in the present embodiment is, for example, tetramethylammonium hydroxide (TMAH), hydrofluoric nitric acid, or hydrofluoric nitric acetic acid.

A rinse liquid supplied from the rinse liquid source 445b is discharged from the nozzle 441b. The rinse liquid is, for example, deionized water (DIW).

The retrieve cup 450 is disposed to surround the rotation holder 431, and retrieves the processing liquid scattered from the glass substrate W by the rotation of the rotation holder 431. A drain port 451 is formed in a bottom of the retrieve cup 450, and a processing liquid retrieved by the retrieve cup 450 is exhausted from the drain port 451 to the outside of the etching apparatus 40. An exhaust port 452 for exhausting the gas supplied from the FFU 421 to the outside of the etching apparatus 40 is formed in the bottom of the retrieve cup 450.

The number of nozzles provided in the etching apparatus 40 is not limited to the above example, and may include, for example, a single nozzle that discharges the etching liquid and the rinse liquid.

When the etching liquid is supplied from the nozzle 441a to the glass substrate W held by the holding member 4311 such that the first surface W1 faces upward, the protective film 60 formed on the first surface W1 of the glass substrate W is removed. At this time, the protective film 60 formed on the second surface W2 and the side surface W3 of the glass substrate W is not removed but remains.

### Configuration of Processing Apparatus Group 50

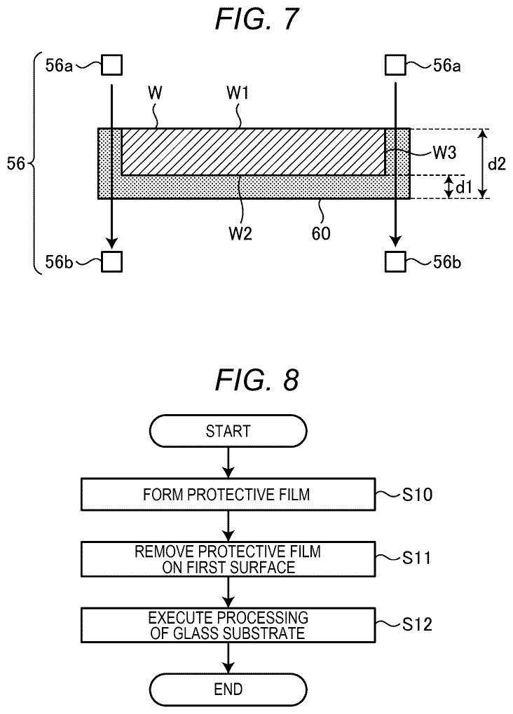

FIG. 6 is a plan view illustrating an example of the processing apparatus group 50. In FIG. 6, components inside some devices are illustrated to be transparent for the sake of convenience. The processing apparatus group 50 includes a vacuum transfer chamber 51, a plurality of processing apparatuses 52, a plurality of load-lock chambers 53, and an atmospheric transfer chamber 54. The vacuum transfer chamber 51 is an example of a transfer chamber.

The processing apparatus 52 is connected to a sidewall of the vacuum transfer chamber 51 through a gate valve G1. In the example of FIG. 6, eight processing apparatuses 52 are connected to the vacuum transfer chamber 51. However, the technique disclosed herein is not limited thereto. The number of processing apparatuses 52 connected to the vacuum transfer chamber 51 may be seven or less, or may be nine or more.

The glass substrate W from which the protective film 60 formed on the first surface W1 is removed by the etching apparatus 40 is loaded into each processing apparatus 52. Further, each of the processing apparatuses 52 performs processing such as film formation or etching on the first surface W1 of the glass substrate W, thereby processing the first surface W1 of the glass substrate W or forming a structure on the first surface W1 of the glass substrate W.

The plurality of load-lock chambers 53 are connected to the other sidewall of the vacuum transfer chamber 51 via gate valves G3. In the example of FIG. 6, two load-lock chambers 53 are connected to the vacuum transfer chamber 51. However, the technique disclosed herein is not limited thereto. The number of load-lock chambers 53 connected to the vacuum transfer chamber 51 may be one, or may be three or more.

A transfer device 511 is disposed in the vacuum transfer chamber 51. The transfer device 511 moves in the vacuum transfer chamber 51 along a guide rail 510 provided in the vacuum transfer chamber 51. Further, the transfer device 511 transfers the glass substrate W between the processing apparatus 52 and the load-lock chamber 53. The vacuum transfer chamber 51 is maintained in a pressure atmosphere lower than an atmospheric pressure. The transfer device 511 may be fixed to a predetermined position in the vacuum transfer chamber 51, and may not be moved in the vacuum transfer chamber 51.

The vacuum transfer chamber 51 is connected to one sidewall of the load-lock chamber 53 through the gate valve G3, and the atmospheric transfer chamber 54 is connected to the other sidewall through a gate valve G4. A plurality of load ports 55 are provided in a sidewall of the atmospheric transfer chamber 54 different from the sidewall of the atmospheric transfer chamber 54 where the gate valve G4 is provided. A container such as a front opening unified pod (FOUP) capable of accommodating the plurality of glass substrates W is connected to each of the load ports 55. The atmospheric transfer chamber 54 may be provided with an aligner module or the like that changes an orientation of the glass substrate W.

The pressure in the atmospheric transfer chamber 54 is the atmospheric pressure. A transfer device 541 is provided in the atmospheric transfer chamber 54. The transfer device 541 moves in the atmospheric transfer chamber 54 along a guide rail 540 provided in the atmospheric transfer chamber 54, and transfers the glass substrate W between the load-lock chamber 53 and the container connected to the load port 55. The transfer device 541 may be fixed to a predetermined position in the atmospheric transfer chamber 54, and may not be moved in the atmospheric transfer chamber 54.

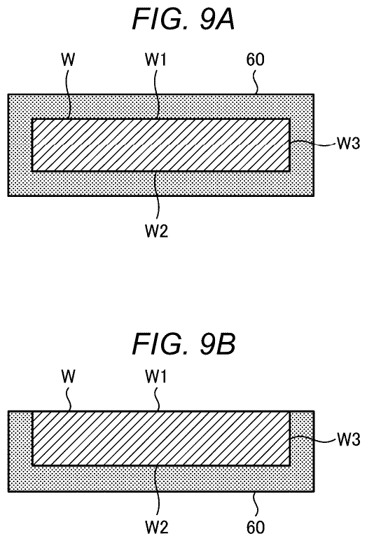

Sensors 56 that detect a position of the glass substrate W are provided in the vicinity of the gate valves G1, the gate valves G3, and the load ports 55. The sensor 56 includes, for example, a light-emitting unit 56a and a light-receiving unit 56b as illustrated in FIG. 7. The light-emitting unit 56a emits visible light of red or the like toward the light-receiving unit 56b. The light-receiving unit 56b outputs, to the control device 20, whether the light emitted from the light-emitting unit 56a is received. The control device 20 detects the position of the glass substrate W based on whether the light emitted from the light-emitting unit 56a is blocked by the glass substrate W.

Since the glass substrate W in the present embodiment transmits light, it is difficult to detect the position of the glass substrate W by the sensor 56. However, in the present embodiment, since the protective film 60 is formed on the surface of the glass substrate W, the light emitted from the light-emitting unit 56a is blocked by the protective film 60 depending on a thickness of the protective film 60, and the position of the glass substrate W can be detected by the sensor 56. However, when the protective film 60 is excessively thick, deformation of the glass substrate W such as warpage may occur due to a difference in stress between the glass substrate W and the protective film 60. When the thickness of the glass substrate W is about 700 μm, the glass substrate W may warp when the thickness of the protective film 60 becomes, for example, 600 nm or more. When the glass substrate W warps, the accuracy of the positions and shapes of holes and trenches may decrease when the processing apparatus 52 performs processing on the glass substrate W. Therefore, it is preferable not to form the protective film 60 on the glass substrate W to an excessive thickness. However, when the protective film 60 is excessively thin, the light emitted from the light-emitting unit 56a passes through the protective film 60.

Here, in the present embodiment, the protective film 60 is also formed on the side surface W3 of the glass substrate W. For example, as illustrated in FIG. 7, the light-emitting unit 56a emits light in a direction along the side surface W3 (a thickness direction of the glass substrate W) with respect to the protective film 60 formed on the side surface W3 of the glass substrate W. Since the glass substrate W has a thickness of 700 μm or more, in the protective film 60 on which the side surface W3 is formed, the protective film 60 has a thickness of 700 μm or more in a direction along the side surface W3. Accordingly, even without forming a particularly thick protective film 60 on the second surface W2 of the glass substrate W, the light emitted from the light-emitting unit 56a can be blocked by the protective film 60 formed on the side surface W3. Accordingly, in the present embodiment, the position of the glass substrate W can be detected by the sensor 56 while preventing the deformation of the glass substrate W.

### Substrate Processing Method

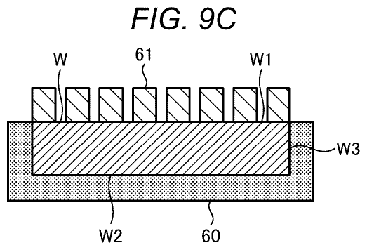

FIG. 8 is a flowchart illustrating an example of a substrate processing method according to a first embodiment. The processing illustrated in FIG. 8 is implemented by the control device 20 controlling each part of the film forming apparatus 30, the etching apparatus 40, and the processing apparatus group 50.

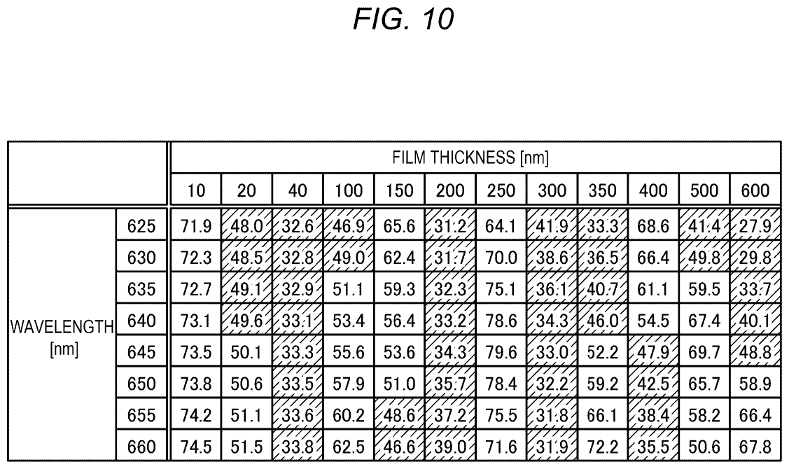

First, the protective film 60 is formed on the glass substrate W (step S10). Step S10 is an example of a process a). In step S10, for example, as illustrated in FIG. 9A, the protective film 60, which is a silicon-containing film, is formed on the first surface W1, the second surface W2, and the side surface W3 of the glass substrate W. In the present embodiment, since the protective film 60 is formed by the film forming apparatus 30, the protective film 60 is simultaneously formed on the first surface W1, the second surface W2, and the side surface W3 of the glass substrate W. In step S10, the glass substrate W is covered with the protective film 60 having a thickness of 40 nm or more and 600 nm or less.

Here, a metal element or the like used in the manufacturing process may adhere to the surface of a commercially available glass substrate W. Therefore, when processing such as etching or film formation is performed by the processing apparatus 52 using a commercially available glass substrate W as it is, members in the chamber of the processing apparatus 52 that come in contact with the glass substrate W may be contaminated with a metal element. When the member in the chamber is contaminated with the metal element, the metal element may mix in the process of etching or a film formation with respect to the glass substrate W, resulting in a defect of the optical element.

In contrast, in the present embodiment, in step S10, the glass substrate W is covered with the protective film 60 having a thickness of 40 nm or more. Accordingly, it is possible to prevent the member or the like in the chamber of the processing apparatus 52 that comes into contact with the glass substrate W from being contaminated with the metal element in the subsequent process of etching or film formation with respect to the glass substrate W.

In step S10, the thickness of the protective film 60 formed on the glass substrate W is controlled to be, for example, 600 nm or less. Accordingly, it is possible to prevent the deformation of the glass substrate W.

Next, the protective film 60 formed on the first surface W1 of the glass substrate W is removed (step S11). Step S11 is an example of a process b). In step S11, for example, as illustrated in FIG. 9B, the protective film 60 formed on the first surface W1 of the glass substrate W is removed by the etching apparatus 40, so that the first surface W1 is exposed.

In step S11, the second surface W2 and the side surface W3 are maintained to be covered with the protective film 60. Accordingly, it is possible to prevent the member (for example, the stage on which the glass substrate W is placed) or the like in the chamber of the processing apparatus 52 that comes into contact with the glass substrate W from being contaminated with the metal element. The protective film 60 formed on at least one of the second surface W2 or the side surface W3 can block the light emitted from the light-emitting unit 56a, so that the position of the glass substrate W can be detected.

Next, processing of the glass substrate W is executed (step S12). Step S12 is an example of a process c). In step S12, for example, as illustrated in FIG. 9C, the processing apparatus 52 of the processing apparatus group 50 performs processing such as etching or film formation on the glass substrate W, so that a structure 61 is formed on the first surface W1 of the glass substrate W. Then, the processing illustrated in the flowchart ends.

The first embodiment is described above. As described above, the substrate processing method in the first embodiment includes a process a) and a process b). In the process a), a silicon-containing film (protective film 60) is formed on the first surface (first surface W1) of the glass substrate (glass substrate W) and the second surface (second surface W2) that is a back surface of the first surface. In the process b), the silicon-containing film formed on the first surface is removed. Accordingly, it is possible to prevent metal contamination caused by the glass substrate.

In the first embodiment described above, in the process a), a film thickness of the silicon-containing film formed on each of the first surface and the second surface of the glass substrate is 40 nm or more. Accordingly, scattering of the metal element adhering to the surface of the glass substrate can be prevented.

In the first embodiment described above, in the process a), the film thickness of the silicon-containing film formed on each of the first surface and the second surface of the glass substrate is preferably 600 nm or less. Accordingly, it is possible to prevent warpage of the glass substrate.

In the first embodiment described above, the silicon-containing film is formed of amorphous silicon or polysilicon. Accordingly, the surface of the glass substrate W can be easily covered with the protective film 60, and the protective film 60 can be easily removed in a removing process.

In the first embodiment described above, in the process a), the silicon-containing film is also formed on the side surface (side surface W3) of the glass substrate. Accordingly, the position of the glass substrate W can be detected by the sensor 56.

The first embodiment described above is the substrate processing system 10, and includes a film forming apparatus (film forming apparatus 30), a removing apparatus (etching apparatus 40), and a processing apparatus (processing apparatus 52). The film forming apparatus forms a silicon-containing film on the first surface of the glass substrate and the second surface, which is the back surface of the first surface, and the removing apparatus removes the silicon-containing film formed on the first surface of the glass substrate. The processing apparatus performs at least one of film formation or etching on the first surface of the glass substrate from which the silicon-containing film is removed. Accordingly, it is possible to prevent metal contamination caused by the glass substrate.

In the first embodiment described above, the substrate processing system further includes a transfer chamber (vacuum transfer chamber 51) that loads the glass substrate into and out of the processing apparatus. The transfer chamber includes a transfer device (transfer device 511) that transfers the glass substrate, and a sensor (56) that detects the position of the glass substrate. The film forming apparatus further forms a silicon-containing film on a side surface of the glass substrate. The sensor detects the position of the glass substrate based on whether light is blocked by the silicon-containing film formed on the side surface of the glass substrate. Accordingly, the position of the glass substrate W can be detected by the sensor 56.

### Second Embodiment

In the first embodiment, after the glass substrate W is covered with the protective film 60, the protective film 60 on the first surface W1 on which the optical element is to be formed is removed, and the optical element is formed on the first surface W1 from which the protective film 60 is removed. In contrast, in the second embodiment, after the glass substrate W is covered with the protective film 60, the protective film 60 formed on the first surface W1 on which the optical element is to be formed is processed to form an optical element that includes a part of the protective film 60 formed on the first surface W1. Hereinafter, the components different from those in the first embodiment will be mainly described.

### Substrate Processing Method

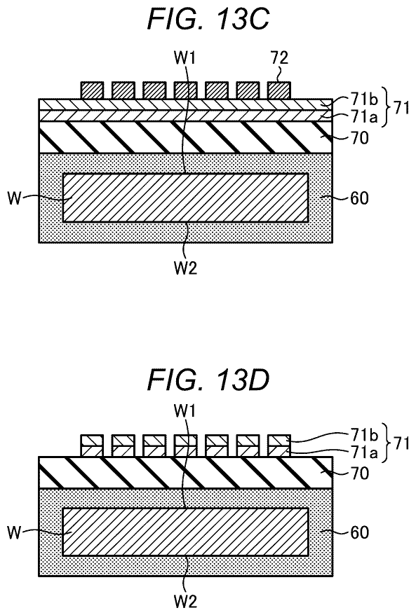

FIG. 12 is a flowchart illustrating an example of a substrate processing method according to a second embodiment. The processing illustrated in FIG. 12 is implemented by the control device 20 controlling each part of the film forming apparatus 30, the etching apparatus 40, and the processing apparatus group 50.

First, the protective film 60 is formed on the glass substrate W (step S20). Step S20 is an example of a process c). In step S20, for example, as illustrated in FIG. 9A, the protective film 60, which is a silicon-containing film, is formed on the first surface W1, the second surface W2, and the side surface W3 of the glass substrate W. In the present embodiment, since the protective film 60 is formed by the film forming apparatus 30, the protective film 60 is simultaneously formed on the first surface W1, the second surface W2, and the side surface W3 of the glass substrate W.

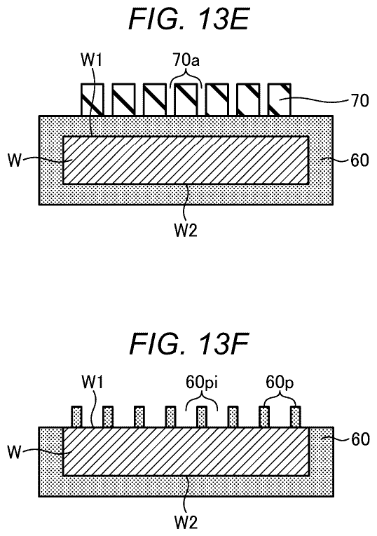

Next, a silicon oxide film is formed (step S21). In step S21, the glass substrate W covered with the protective film 60 is loaded into the film forming apparatus in the processing apparatus group 50. Then, a silane-containing gas such as a monosilane gas is introduced as a raw material gas into the film forming apparatus, and an oxygen-containing gas such as an oxygen gas or an ozone gas is introduced as a reaction gas. Accordingly, for example, as illustrated in FIG. 13A, a silicon oxide film 70 is formed on the protective film 60 formed on the first surface W1 of the glass substrate W.

The silicon oxide film 70 may be formed by, in addition to a chemical vapor deposition (CVD) method, a physical vapor deposition (PVD) method, an atomic layer deposition (ALD) method, spin coating, or the like.

When the thickness of the protective film 60 formed on the first surface W1 is less than the thickness necessary for forming the optical element in step S20, a step of further forming the protective film 60 on the protective film 60 formed on the first surface W1 may be performed between step S20 and S21. The process of forming the protective film 60 on the protective film 60 formed on the first surface W1 is an example of a process e).

When the thickness of the protective film 60 formed on the first surface W1 is larger than the thickness necessary for forming the optical element in step S20, an etching process may be performed to reduce the thickness of the protective film 60 formed on the first surface W1 between steps S20 and S21. The etching process of reducing the thickness of the protective film 60 formed on the first surface W1 is an example of a process f).

In step S20, when the thickness of the protective film 60 formed on the first surface W1 is less than the thickness necessary for forming the optical element, the protective film 60 is further formed on the protective film 60 formed on the first surface W1, between steps S20 and S21. Then, the thickness of the protective film 60 may be finely adjusted by etching the protective film 60 until the thickness of the formed protective film 60 becomes a thickness necessary for forming the optical element.

Next, a hard mask is formed (step S22). In step S22, the glass substrate W on which the silicon oxide film 70 is formed is loaded into a coating apparatus in the processing apparatus group 50. Then, the processing liquid for forming a hard mask is applied on the silicon oxide film 70 by the coating apparatus, and as illustrated in, for example, FIG. 13B, a hard mask 71 that includes a spin-on carbon film 71a and a spin-on glass film 71b is formed on the silicon oxide film 70.

In the example of FIG. 13B, the hard mask 71 includes two layers of the spin-on carbon film 71a and the spin-on glass film 71b. However, the hard mask 71 may include either the spin-on carbon film 71a or the spin-on glass film 71b alone. The hard mask 71 may include a metal-containing film, a silicon oxynitride film, a back surface antireflection film, or the like.

Next, a resist film is formed (step S23). In step S23, for example, in the coating apparatus, a processing liquid for forming a resist film is applied onto the hard mask 71, so that the resist film is formed on the hard mask 71. Then, the glass substrate W on which the resist film is formed is loaded into an exposure apparatus in the processing apparatus group 50, and a predetermined pattern is exposed to the resist film. Then, the glass substrate W on which the predetermined pattern is exposed to the resist film is loaded into a developer in the processing apparatus group 50 and developed. Accordingly, for example, as illustrated in FIG. 13C, a resist film 72 having a predetermined pattern is formed on the hard mask 71.

The resist film 72 is, for example, a photoresist film for extreme ultraviolet (EUV). The pattern formation of the resist film may be performed by, for example, disposing a mold (mask) on which a pattern is formed on the resist film and curing the resist film of a resin by performing irradiation with ultraviolet rays, thermal treatment, or the like through the mold. The pattern formation of the resist film may be performed by nanoimprint lithography.

Next, the hard mask 71 and the silicon oxide film 70 are etched (step S24). In step S24, the glass substrate W on which the resist film 72 having the predetermined pattern is formed is loaded into the etching apparatus in the processing apparatus group 50. Then, by introducing an etching gas such as a fluorine-containing gas into the etching apparatus, the hard mask 71 is etched using the resist film 72 as a mask. Accordingly, for example, as illustrated in FIG. 13D, the pattern corresponding to the resist film 72 is transferred to the hard mask 71.

Then, by introducing an etching gas such as a fluorine-containing gas into the etching apparatus, the silicon oxide film 70 is etched using the hard mask 71 on which the pattern of the resist film 72 is transferred as a mask. Accordingly, for example, as illustrated in FIG. 13E, the pattern corresponding to the hard mask 71 is transferred to the silicon oxide film 70. The etching of the silicon oxide film 70 is performed until the protective film 60 is exposed from the bottom of an opening 70a of the silicon oxide film 70.

Next, the protective film 60 is etched (step S25). In step S25, the protective film 60 formed on the first surface W1 is etched using the silicon oxide film 70 on which the pattern of the hard mask 71 is transferred as a mask by introducing an etching gas such as a fluorine-containing gas into the etching apparatus. Accordingly, for example, as illustrated in FIG. 13F, a pattern 60p of the protective film 60 corresponding to the pattern of the hard mask 71 is formed. The etching of the protective film 60 is performed until the first surface W1 of the glass substrate W is exposed from the bottom of an opening 60pi of the protective film 60. Steps S21 to S25 are an example of a process d).

The second embodiment is described above. As described above, the substrate processing method in the second embodiment includes a process c) and a process d). In the process c), a silicon-containing film is formed on the second surface, which is the back surface of the first surface and the first surface of the glass substrate. In the process d), a pattern is formed on the silicon-containing film formed on the first surface. Accordingly, it is possible to prevent metal contamination caused by the glass substrate when a pattern is formed on the silicon-containing film formed on the first surface.

The substrate processing method in the second embodiment described above may include a process e). The process e) is performed before the process d), and a silicon-containing film is further formed on the silicon-containing film formed on the first surface to increase the thickness of the silicon-containing film formed on the first surface. Accordingly, an optical element including the protective film 60 having a desired thickness can be formed.

The substrate processing method in the second embodiment described above may include a process f). The process f) is performed before the process d), and etches the silicon-containing film formed on the first surface to reduce the thickness of the silicon-containing film formed on the first surface. Accordingly, an optical element including the protective film 60 having a desired thickness can be formed.

The second embodiment described above is the substrate processing system 10, and includes a film forming apparatus (film forming apparatus 30) and a processing apparatus (processing apparatus group 50). The film forming apparatus forms a silicon-containing film on the first surface of the glass substrate and the second surface, which is the back surface of the first surface, and the processing apparatus forms a pattern on the silicon-containing film formed on the first surface by executing processing of at least one of film formation or etching on the silicon-containing film formed on the first surface. Accordingly, it is possible to prevent metal contamination caused by the glass substrate when a pattern is formed on the silicon-containing film formed on the first surface.

### Other

The technology disclosed in the present application is not limited to the above-described embodiments, and various modifications are possible within the scope of the gist thereof.

For example, in each embodiment described above, the position of the glass substrate W is detected based on whether the light emitted from the light-emitting unit 56a is blocked by the protective film 60 formed on the side surface W3 of the glass substrate W, and the technique disclosed herein is not limited thereto. For example, the protective film 60 may be thickly formed on the second surface W2 of the glass substrate W within the range of 600 nm or less. Accordingly, the position of the glass substrate W can be detected based on whether the light emitted from the light-emitting unit 56a is blocked by the protective film 60 formed on the second surface W2. Accordingly, the position of the glass substrate W can be more easily detected.

From the viewpoint of shortening a time required for forming the protective film 60 and prevention of warpage of the glass substrate W, the protective film 60 is preferably thinner. However, when the protective film 60 is excessively thin, the transmittance of the light emitted from the light-emitting unit 56 a exceeds 50%, depending on the material of the protective film 60. When the transmittance of the light emitted from the light-emitting unit 56a is 50% or less, the position of the glass substrate W can be detected depending on a setting of threshold values.

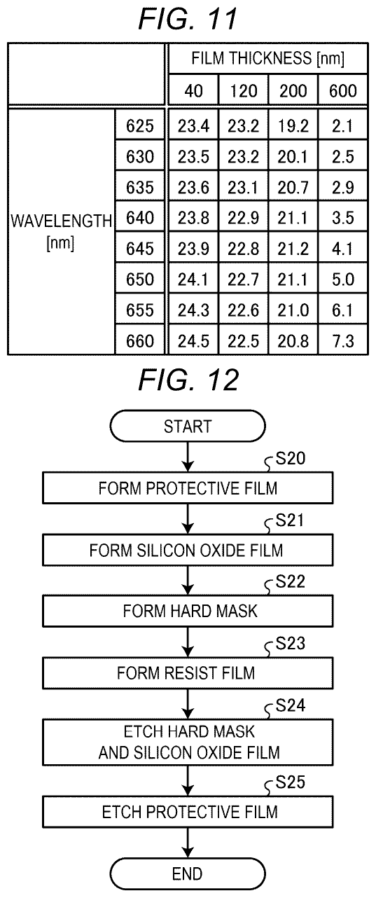

When the protective film 60 is polysilicon, the transmittance (%) of each combination of a film thickness of the protective film 60 and a wavelength of light is, for example, as illustrated in FIG. 10. In the example of FIG. 10, a wavelength of red light (625 nm to 660 nm) commonly used by sensors in visible light is illustrated.

Referring to FIG. 10, when the film thickness of the protective film 60 is in the range of 20 nm to 200 nm and 300 nm to 600 nm, the transmittance is less than 50% with respect to light of any wavelength. Therefore, when the protective film 60 is polysilicon, it is preferable to have a film thickness in the range of 20 nm to 200 nm and 300 nm to 600 nm.

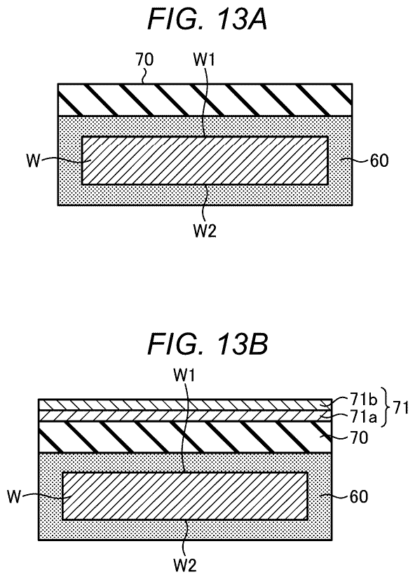

When the protective film 60 is amorphous silicon, the transmittance (%) of each combination of the film thickness of the protective film 60 and the wavelength of light is, for example, as illustrated in FIG. 11. Referring to FIG. 11, in the film thickness in the entire range of 40 nm to 600 nm, the transmittance of light of any wavelength in the range of 625 nm to 660 nm is less than 50%. Therefore, when the protective film 60 is amorphous silicon, the position of the glass substrate W can be detected as long as the film thickness is in a range of 40 nm to 600 nm.

Since the glass substrate W is an insulator, the glass substrate W cannot be adsorbed to the electrostatic chuck by an electrostatic force. However, depending on the film thickness of the protective film 60 that is a silicon-containing film, the glass substrate W on which the protective film 60 is formed can be adsorbed onto the electrostatic chuck. For example, when the protective film 60 having a thickness of 500 nm or more is formed on the second surface W2 of the glass substrate W, the glass substrate W can be adsorbed onto the electrostatic chuck. Accordingly, the glass substrate W can be adsorbed to the electrostatic chuck without separately forming a conductive film on the glass substrate W.

The protective film 60 that is a silicon-containing film may be doped with an impurity other than silicon. Examples of the impurity doped into the protective film 60 include phosphorus, boron, arsenic, antimony, aluminum, and gallium. Since the conductivity of the protective film 60 can be improved depending on the type of the impurity, the glass substrate W can be adsorbed to the electrostatic chuck even when the protective film 60 is thinner.

According to various aspects and embodiments of the present disclosure, one or more problems caused by the fact that a processing target is a glass substrate can be overcome, and processing such as film formation or etching can be performed on the glass substrate.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

The following appendixes will be further disclosed with respect to the above-described embodiments.

### Appendix 1

A Substrate processing method includes:
a) forming a silicon-containing film on each of a first surface and a second surface, which is a back surface of the first surface, of a glass substrate; and
b) removing the silicon-containing film formed on the first surface.

### Appendix 2

In the substrate processing method according to Appendix 1, in a), a film thickness of the silicon-containing film formed on each of the first surface and the second surface of the glass substrate is 40 nm or more.

### Appendix 3

In the substrate processing method according to Appendix 1 or 2, in a), a film thickness of the silicon-containing film formed on each of the first surface and the second surface of the glass substrate is 600 nm or less.

### Appendix 4

In the substrate processing method according to any one of Appendices 1 to 3, the silicon-containing film is formed of amorphous silicon, polysilicon, or silicon to which at least one of phosphorus or boron is added.

### Appendix 5

In the substrate processing method according to Appendix 4, the silicon-containing film is formed of polysilicon, and in a), a film thickness of the silicon-containing film formed on each of the first surface and the second surface of the glass substrate is 20 nm or more and 200 nm or less, or 300 nm or more and 600 nm or less.

### Appendix 6

In the substrate processing method according to Appendix 4, the silicon-containing film is formed of amorphous silicon, and in a), a film thickness of the silicon-containing film formed on each of the first surface and the second surface of the glass substrate is 20 nm or more and 600 nm or less.

### Appendix 7

In the substrate processing method according to any one of Appendices 1 to 6, in a), a film thickness of the silicon-containing film formed on each of the first surface and the second surface of the glass substrate is 500 nm or more.

### Appendix 8

The substrate processing method according to any one of Appendices 1 to 7, wherein in a), the silicon-containing film is also formed on a side surface of the glass substrate.

### Appendix 9

A substrate processing system includes:
a film forming apparatus configured to form a silicon-containing film on each of a first surface and a second surface, which is a back surface of the first surface, of a glass substrate, a removing apparatus configured to remove the silicon-containing film formed on the first surface of the glass substrate, and
a processing apparatus configured to execute processing of at least one of film formation or etching on the first surface of the glass substrate from which the silicon-containing film is removed.

### Appendix 10

The substrate processing system according to Appendix 9, further includes: a transfer chamber configured to allow the glass substrate to be loaded into and out of the processing apparatus, in which
the transfer chamber has
   a transfer device configured to transfer the glass substrate, and
   a sensor configured to detect a position of the glass substrate,
the film forming apparatus further forms the silicon-containing film on a side surface of the glass substrate, and
the sensor detects the position of the glass substrate based on whether light is blocked by the silicon-containing film formed on at least one of the second surface or the side surface of the glass substrate.

### Appendix 11

A substrate processing method includes:
c) forming a silicon-containing film on each of a first surface and a second surface, which is a back surface of the first surface, of a glass substrate, and
d) forming a pattern on the silicon-containing film formed on the first surface.

### Appendix 12

The substrate processing method according to Appendix 11, further includes:
e) before execution of d), further forming the silicon-containing film on the silicon-containing film formed on the first surface to increase a thickness of the silicon-containing film formed on the first surface.

### Appendix 13

The substrate processing method according to Appendix 11 or 12, further includes:
f) before execution of d), etching the silicon-containing film formed on the first surface to reduce a thickness of the silicon-containing film formed on the first surface.

### Appendix 14

In the substrate processing method according to any one of Appendices 11 to 13, in c), a film thickness of the silicon-containing film formed on each of the first surface and the second surface of the glass substrate is 40 nm or more.

### Appendix 15

In the substrate processing method according to any one of Appendices 11 to 14, in c), a film thickness of the silicon-containing film formed on each of the first surface and the second surface of the glass substrate is 600 nm or less.

### Appendix 16

In the substrate processing method according to any one of Appendices 11 to 15, the silicon-containing film is formed of amorphous silicon, polysilicon, or silicon to which at least one of phosphorus or boron is added.

### Appendix 17

In the substrate processing method according to Appendix 16,
the silicon-containing film is formed of polysilicon, and in c), a film thickness of the silicon-containing film formed on each of the first surface and the second surface of the glass substrate is 20 nm or more and 200 nm or less, or 300 nm or more and 600 nm or less.

### Appendix 18

In the substrate processing method according to Appendix 16, the silicon-containing film is formed of amorphous silicon, and in c), a film thickness of the silicon-containing film formed on each of the first surface and the second surface of the glass substrate is 20 nm or more and 600 nm or less.

### Appendix 19

In the substrate processing method according to any one of Appendices 11 to 18, in c), a film thickness of the silicon-containing film formed on each of the first surface and the second surface of the glass substrate is 500 nm or more.

### Appendix 20

In the substrate processing method according to any one of Appendices 11 to 19, in c), the silicon-containing film is also formed on a side surface of the glass substrate.

### Appendix 21

A substrate processing system includes:
a film forming apparatus configured to form a silicon-containing film on each of a first surface and a second surface, which is a back surface of the first surface, of a glass substrate, and
a processing apparatus configured to form a pattern on the silicon-containing film formed on the first surface by executing processing of at least one of film formation or etching on the silicon-containing film formed on the first surface.

### Appendix 22

The substrate processing system according to Appendix 21, further includes:
a transfer chamber configured to allow the glass substrate to be loaded into and out of the processing apparatus, in which
the transfer chamber has
   a transfer device configured to transfer the glass substrate, and
   a sensor configured to detect a position of the glass substrate,
the film forming apparatus further forms the silicon-containing film on a side surface of the glass substrate, and
the sensor detects the position of the glass substrate based on whether light is blocked by the silicon-containing film formed on at least one of the second surface or the side surface of the glass substrate.

1. A substrate processing method comprising:
a) forming a silicon-containing layer on each of a first surface and a second surface, the second surface is a back surface of the first surface, of a glass substrate; and
b) removing the silicon-containing layer formed on the first surface.

2. The substrate processing method according to claim 1, wherein
in a), a layer thickness of the silicon-containing layer formed on each of the first surface and the second surface of the glass substrate is 40 nm or more.

3. The substrate processing method according to claim 1, wherein
in a), a layer thickness of the silicon-containing layer formed on each of the first surface and the second surface of the glass substrate is 600 nm or less.

4. The substrate processing method according to claim 1, wherein
the silicon-containing layer is formed of amorphous silicon, polysilicon, or silicon to which at least one of phosphorus or boron is added.

5. The substrate processing method according to claim 4, wherein
the silicon-containing layer is formed of polysilicon, and
in a), a layer thickness of the silicon-containing layer formed on each of the first surface and the second surface of the glass substrate is 20 nm or more and 200 nm or less, or 300 nm or more and 600 nm or less.

6. The substrate processing method according to claim 4, wherein
the silicon-containing layer is formed of amorphous silicon, and
in a), a layer thickness of the silicon-containing layer formed on each of the first surface and the second surface of the glass substrate is 20 nm or more and 600 nm or less.

7. The substrate processing method according to claim 1, wherein
in a), a layer thickness of the silicon-containing layer formed on each of the first surface and the second surface of the glass substrate is 500 nm or more.

8. The substrate processing method according to claim 1, wherein
in a), the silicon-containing layer is also formed on a side surface of the glass substrate.

9. A substrate processing system comprising:
a layer forming apparatus to form a silicon-containing layer on each of a first surface and a second surface, which is a back surface of the first surface, of a glass substrate;
a removing apparatus to remove the silicon-containing layer formed on the first surface of the glass substrate; and
a processing apparatus to execute processing of at least one of layer formation or etching on the first surface of the glass substrate from which the silicon-containing layer is removed.

10. The substrate processing system according to claim 9, further comprising:
a transfer chamber to allow the glass substrate to be loaded into and out of the processing apparatus, wherein
the transfer chamber has
a transfer device to transfer the glass substrate, and
a sensor configured to detect a position of the glass substrate,
the layer forming apparatus further forms the silicon-containing film on a side surface of the glass substrate, and
the sensor detects the position of the glass substrate based on whether light is blocked by the silicon-containing layer formed on at least one of the second surface or the side surface of the glass substrate.

11. A substrate processing method comprising:
c) forming a silicon-containing layer on each of a first surface and a second surface, the second surface is a back surface of the first surface, of a glass substrate; and
d) forming a pattern on the silicon-containing layer formed on the first surface.

12. The substrate processing method according to claim 11, further comprising:
e) before execution of d), further forming the silicon-containing layer on the silicon-containing layer formed on the first surface to increase a thickness of the silicon-containing layer formed on the first surface.

13. The substrate processing method according to claim 11, further comprising:
f) before execution of d), etching the silicon-containing layer formed on the first surface to reduce a thickness of the silicon-containing layer formed on the first surface.

14. A substrate processing system comprising:
a layer forming apparatus to form a silicon-containing layer on each of a first surface and a second surface, the second surface is a back surface of the first surface, of a glass substrate; and
a processing apparatus to form a pattern on the silicon-containing layer formed on the first surface by executing processing of at least one of layer formation or etching on the silicon-containing layer formed on the first surface.

15. The substrate processing system according to claim 14, further comprising:
a transfer chamber to allow the glass substrate to be loaded into and out of the processing apparatus, wherein
the transfer chamber has
a transfer device to transfer the glass substrate, and
a sensor configured to detect a position of the glass substrate,
the layer forming apparatus further forms the silicon-containing layer on a side surface of the glass substrate, and
the sensor detects the position of the glass substrate based on whether light is blocked by the silicon-containing layer formed on at least one of the second surface or the side surface of the glass substrate.

16. The substrate processing method according to claim 2, wherein
in a), a layer thickness of the silicon-containing layer formed on each of the first surface and the second surface of the glass substrate is 600 nm or less.

17. The substrate processing method according to claim 2, wherein
the silicon-containing layer is formed of amorphous silicon, polysilicon, or silicon to which at least one of phosphorus or boron is added.

18. The substrate processing method according to claim 2, wherein
in a), a layer thickness of the silicon-containing layer formed on each of the first surface and the second surface of the glass substrate is 500 nm or more.

19. The substrate processing method according to claim 1, wherein
in a), the silicon-containing layer is also formed on a side surface of the glass substrate.

20. The substrate processing method according to claim 12, further comprising:
f) before execution of d), etching the silicon-containing layer formed on the first surface to reduce a thickness of the silicon-containing layer formed on the first surface.
